(19) United States
(12) Patent Application Publication
(10) Pub. No.: US 2024/0310486 A1
(43) Pub. Date: Sep. 19, 2024

(54) LIDAR, AUTONOMOUS DRIVING SYSTEM, AND MOBILE DEVICE

(71) Applicant: SUTENG INNOVATION TECHNOLOGY CO., LTD., Shenzhen (CN)

(72) Inventor: Zhihong QI, Shenzhen (CN)

(73) Assignee: SUTENG INNOVATION TECHNOLOGY CO., LTD., Shenzhen (CN)

(21) Appl. No.: 18/582,623

(22) Filed: Feb. 20, 2024

(30) Foreign Application Priority Data
Mar. 16, 2023 (CN) 202310303643.2

(51) Int. Cl. G01S 7/481

(52) U.S. Cl. CPC G01S 7/4811; G01S 7/4817

(57) ABSTRACT

Embodiments of this application disclose a LiDAR, an autonomous driving system, and a mobile device. The LiDAR includes an emitter, a receiver, a beam splitter, a transceiver lens, a scanner, and an extinction module. Along a transmission path of detection light, the beam splitter is downstream of the emitter, the transceiver lens is downstream of the beam splitter, and the scanner is downstream of the transceiver lens. Along a transmission path of echo light, the beam splitter is upstream of the receiver, the transceiver lens is upstream of the beam splitter, and the scanner is upstream of the transceiver lens, the detection light and the echo light share the transceiver lens. The extinction module includes a first extinctor positioned at an outgoing end of the emitter, a second extinctor positioned at a receiving end of the receiver, and a third extinctor positioned between the transceiver lens and the scanner.

### CROSS-REFERENCE TO RELATED APPLICATION

The present application claims the benefit of priority to Chinese Patent Application No. 202310303643.2, filed on Mar. 16, 2023, which is hereby incorporated by reference in its entirety.

### TECHNICAL FIELD

This application relates to the field of laser detection technology, particularly to a LIDAR, an autonomous driving system, and a mobile device.

### TECHNICAL BACKGROUND

A LIDAR is a radar system that emits laser beams to detect the characteristics of a target, such as location and speed, which involves emitting a detection laser beam towards the target and then comparing the received signal, which is reflected back from the target, with the emitted signal. After appropriate processing, this comparison yields information about the target, such as distance, azimuth, height, speed, attitude, and even shape.

LiDAR systems often encounter stray light during operation. For example, due to the size requirements of the entire LiDAR system, scanners such as rotating mirrors and galvanometers are confined within a certain range. As a result, some light beams may not propagate along the predetermined path, thus creating stray light. This stray light can reach the receiver, causing it to receive not only the echo signal reflected by the target object but also the stray light signal, which affects the detection accuracy of the LiDAR.

### SUMMARY

The present embodiments provide a LiDAR, an autonomous driving system, and a mobile device.

In a first aspect, the present embodiments provide a LIDAR, comprising: an emitter configured to emit detection light to a target object in a target region; a receiver configured to receive echo light reflected by the target object, the echo light is a reflected light of the detection light; a beam splitter downstream of the emitter along a transmission path of the detection light, and upstream of the receiver along a transmission path of the echo light; a transceiver lens downstream of the beam splitter along the transmission path of the detection light, and upstream of the beam splitter along the transmission path of the echo light; a scanner downstream of the transceiver lens along the transmission path of the detection light, and upstream of the transceiver lens along the transmission path of the echo light; an extinction module includes a first extinctor positioned at an outgoing end of the emitter, a second extinctor positioned at a receiving end of the receiver, and a third extinctor positioned between the transceiver lens and the scanner.

In a second aspect, embodiments of the present disclosure provide an autonomous driving system including the foregoing LiDAR.

In a third aspect, embodiments of the present disclosure provide a mobile device including the foregoing LiDAR, or the autonomous driving system.

The LiDAR, autonomous driving system, and mobile device provided in the present disclosure reduce the size and manufacturing cost of the LiDAR by designing the position of the beam splitter to allow for the shared use of the transceiver lens for both the detection light and the echo light, compared to using different lenses for the transmission paths of the detection light and the echo light. By providing extinction modules at the outgoing end of the emitter, the receiving end of the receiver, and between the transceiver lens and the scanner, stray light from multiple parts of the LiDAR can be eliminated, thereby improving the detection accuracy of the LiDAR.

### BRIEF DESCRIPTION OF DRAWINGS

To provide a clearer explanation of the technical solutions in the embodiments of this application, the following is a brief description of the drawings used in the description of the embodiments. The drawings described below are only some embodiments of this disclosure.

FIG. 1 is a schematic structural diagram of a mobile device provided by an embodiment of this application;

FIG. 2 is a schematic block diagram of the structure of a mobile device provided by an embodiment of this application;

FIG. 3 is a partial schematic diagram of a LIDAR provided by an embodiment of this application;

FIG. 4 is a schematic diagram of a structure of a beam splitter in a LIDAR provided by an embodiment of this application;

FIG. 5 is another schematic diagram of a structure of a beam splitter in a LIDAR provided by an embodiment of this application;

FIG. 6 is a schematic diagram of the structure of a first extinctor in a LIDAR provided by an embodiment of this application;

FIG. 7 is a schematic diagram of the structure of a first sub-extinctor of a second extinctor in a LIDAR provided by an embodiment of this application;

FIG. 8 is a schematic diagram of the structure of a third extinctor in a LIDAR provided by an embodiment of this application;

FIG. 9 is a partial schematic diagram of the LiDAR shown in FIG. 3 in another state of use; and

FIG. 10 is a perspective diagram of the LiDAR provided by an embodiment of this application with one end plate removed.

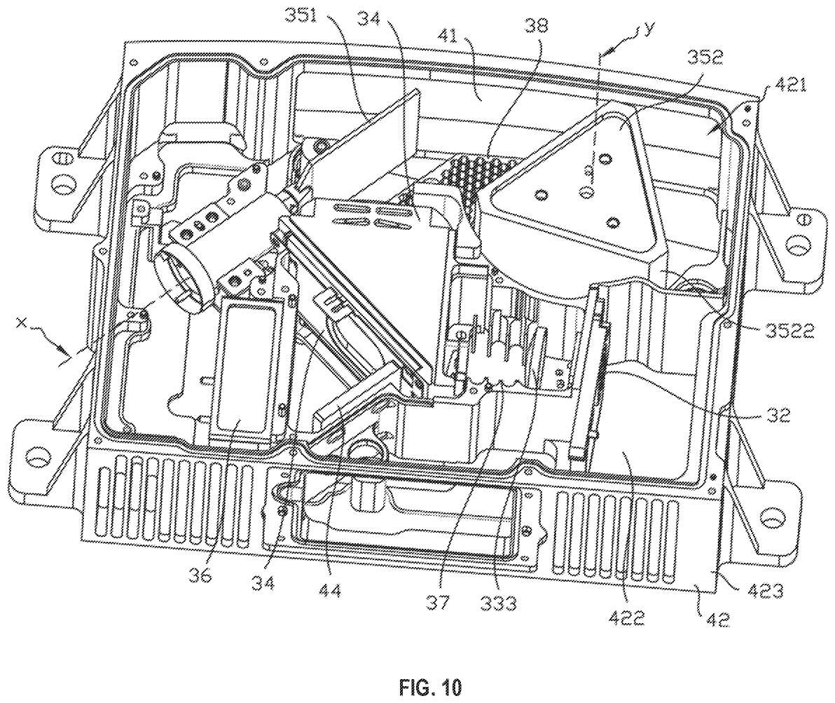

### DESCRIPTION OF REFERENCE NUMERALS

1—Mobile device; 2—Autonomous driving system; 3—LiDAR; 31—Emitter; 32—Receiver; 332—Emitting lens; 333—Receiving lens; 331—Transceiver lens; 34—Beam splitter; 341—Reflection part; 342—Transmission part; 343—First surface; 344—Second surface; 345—First light-transmitting hole; 35—Scanner; 351—Galvanometer; 3511—First reflection surface; 352—Polygon mirror; 3521—Second reflection surface; 3522—Transition surface; 36—First extinctor; 361—Second light-transmitting hole; 3611—Extinction groove; 362—First end face; 3621—First mounting groove; 363—Second end face; 3631—Second mounting groove; 37—Second extinctor; 371—First sub-extinctor; 3711—Extinction diaphragm; 3712—Third light-transmitting hole; 3713—Mounting cylinder; 372—Second sub-extinctor; 3721—Extinction unit; 3722—Extinction teeth; 38—Third extinctor; 381—Extinction hole; 39—Optical filter; 41—Light-transmitting plate; 42—Housing; 421—Mounting cavity; 422—Side plate; 423—End plate; 43—Isolation piece; 44—Optical path conversion element; x-First axis; y-Second axis.

### DETAILED DESCRIPTION

To make objectives, technical solutions, and advantages of the present disclosure clearer, embodiments of the present disclosure are described in further detail below with reference to the drawings.

When the following description refers to the drawings, unless otherwise indicated, the same numbers in different drawings indicate the same or similar elements, the implementations are merely examples of devices and methods consistent with some aspects of the appended claims as detailed in the present disclosure.

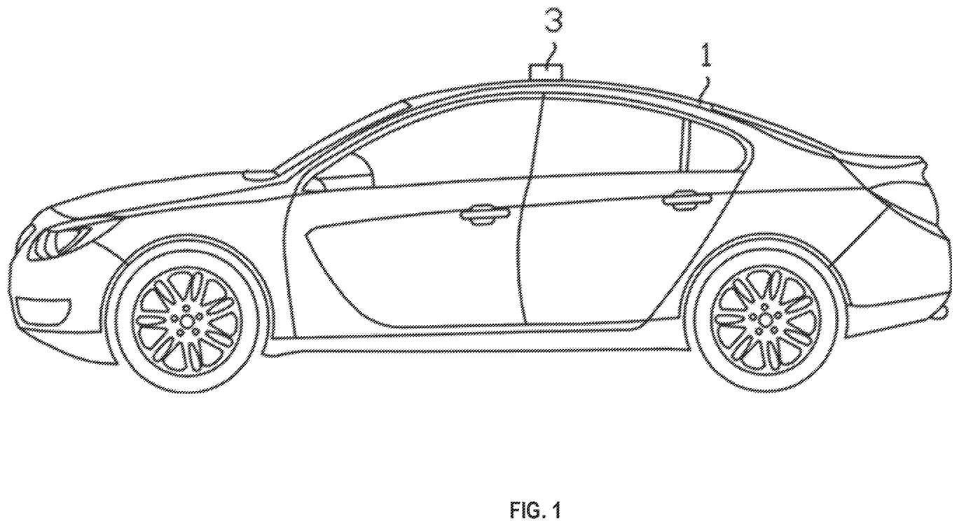

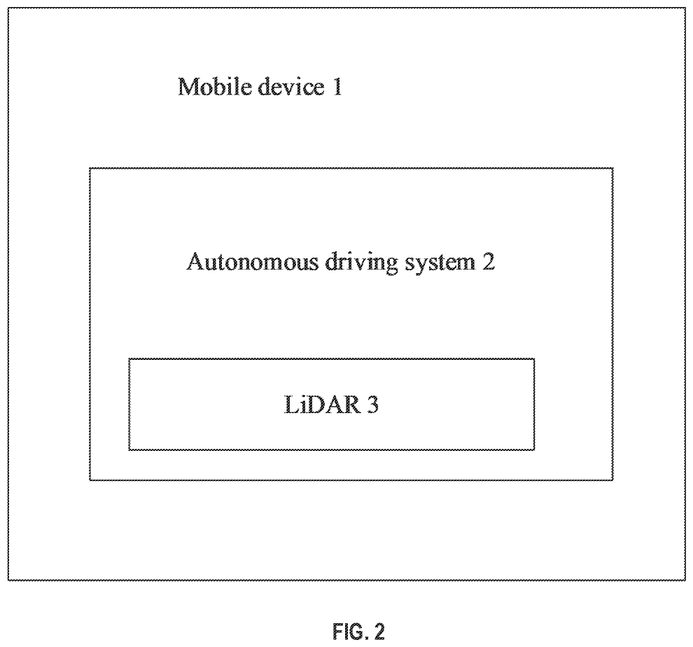

Referring to FIG. 1 and FIG. 2, an embodiment of this application provides a mobile device 1. The mobile device 1 includes a LiDAR 3. In some embodiments, the mobile device 1 includes an autonomous driving system 2. The mobile device 1 may be a device including the LIDAR 3 or the autonomous driving system 2, such as a vehicle, a drone, a robot, or the like. In some embodiments, when the mobile device 1 includes the autonomous driving system 2, the autonomous driving system 2 includes the LiDAR 3.

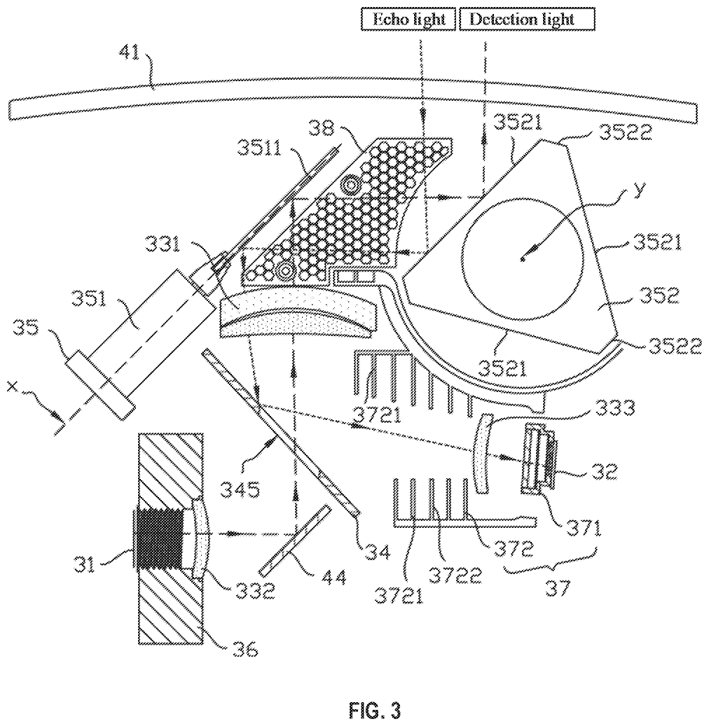

Referring to FIG. 3, the LiDAR 3 includes an emitter 31 and a receiver 32. The emitter 31 is configured to emit detection light to a target object in a target region. The receiver 32 is configured to receive echo light reflected of the detection light reflected back by the target object, output an electrical signal corresponding to the echo light, and the electrical signal is then processed by a signal processing unit to form a point cloud. The distance, azimuth, height, speed, attitude, and shape of the target object can be obtained by processing the point cloud, to implement the LiDAR function, and then can be applied to navigation avoidance, obstacle identification, ranging, speed measurement, and autonomous driving of a product such as a vehicle, a robot, a logistics vehicle, or a patrol vehicle.

In addition to being used in a field of laser detection technology, the LiDAR 3 may also be used in other application scenarios, such as a field of part diameter detection, a field of surface roughness detection, a field of strain detection, a field of displacement detection, a field of vibration detection, a field of speed detection, a field of distance detection, a field of acceleration detection, and a field of shape detection of an object.

The emitter 31 can be a laser emitter in various forms. For example, the emitter 31 can be a vertical-cavity surface-emitting laser (VCSEL), an edge emitting laser (EEL), an LD light source, and the like. The receiver 32 can be a silicon photomultiplier (SiPM), an avalanche photodiode (APD), a single-photon avalanche diode (SPAD), and the like.

Further, the LiDAR 3 further includes a transceiver lens 331, a beam splitter 34, a scanner 35, and an extinction module.

Along the transmission path of the detection light, the beam splitter 34 is downstream of the emitter 31, the transceiver lens 331 is downstream of the beam splitter 34, and the scanner 35 is downstream of the transceiver lens 331. Along the transmission path of the echo light, the receiver 32 is downstream of the beam splitter 34, the beam splitter 34 is downstream of the transceiver lens 331, and the transceiver lens 331 is downstream of the scanner 35. The beam splitter 34 is arranged in the position, which can enable the detection light and the echo light to share the transceiver lens 331. Compared with arranging different lenses in the transmission path of the detection light and the transmission path of the echo light respectively, the size and manufacturing cost of the LiDAR 3 can be reduced.

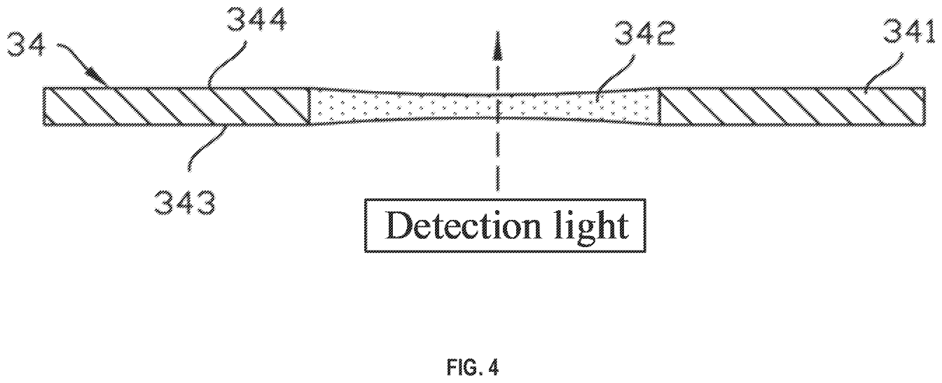

In an embodiment, referring to FIG. 4, the beam splitter 34 may include a reflection part 341 and a transmission part 342 connected to the reflection part 341. The reflection part 341 may be configured to reflect one of the detection light and the echo light, and the transmission part 342 may be configured to transmit the other one of the detection light and the echo light. The transmission part 342 may be recessed relative to the reflection part 341 to reduce a thickness of a medium that the light passes through the transmission part 342, thereby reducing the loss.

In some embodiments, the beam splitter 34 has a first surface 343 and a second surface 344 opposite to each other. If the transmission part 342 is configured to allow the detection light (echo light) to pass through, the detection light (echo light) can pass through the first surface 343 to the second surface 344. The recess of the transmission part 342 relative to the reflection part 341 can be that a part region of the first surface 343 corresponding to the transmission part 342 is recessed relative to a part region of the first surface 343 corresponding to the reflection part 341, and/or a part region of the second surface 344 corresponding to the transmission part 342 is recessed relative to a part region of the second surface 344 corresponding to the reflection part 341.

In some embodiments, the reflection part 341 may be made of a material having a reflection function, or the reflection part 341 may be made of any material and the reflection part 341 is arranged in a way that a part region of the first surface 343 corresponding to the reflection part 341 and/or a part region of the second surface 344 corresponding to the reflection part 341 is disposed with reflection coating, so that the reflection part 341 has the reflection function. The transmission part 342 may be made of a material having a light transmission function. In addition, a part region of the first surface 343 corresponding to the transmission part 342 and/or a part region of the second surface 344 corresponding to the transmission part 342 may also be provided with an anti-reflective coating, to improve a light transmission performance of the transmission part 342.

In some implementations, the reflection part 341 may be disposed at a periphery of the transmission part 342, or the transmission part 342 may be disposed at a periphery of the reflection part 341.

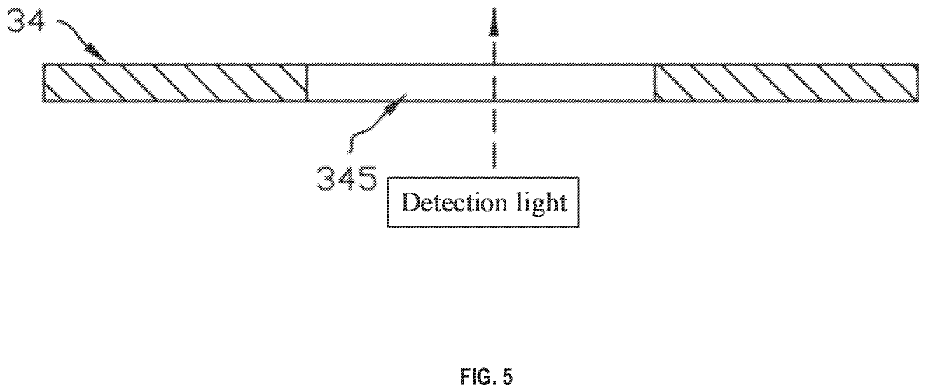

In an embodiment, referring to FIG. 5, the beam splitter 34 may be provided with a first light-transmitting hole 345. The beam splitter 34 may be configured to reflect one of the detection light and the echo light, and the first light-transmitting hole 345 may be configured to pass through the other one of the detection light and the echo light. Directly passing through the detection light or the echo light via the first light-transmitting hole 345 on the beam splitter 34 can reduce light loss compared with including a transmission part in the beam splitter 34 and providing an anti-reflective coating on the transmission part, and the number of coatings can be reduced, thereby reducing processing costs.

In some embodiments, the beam splitter 34 can be made of a material having a reflection function, or the beam splitter 34 can be made of any material, and a reflection coating is disposed on the surface of the beam splitter 34, so that the beam splitter 34 has the reflection function.

In some embodiments, the first light-passing hole 345 may be disposed at the middle of the beam splitter 34.

Referring to FIG. 3, the LiDAR 3 can further include an emitting lens 332 and a receiving lens 333. Along the transmission path of the detection light, the emitting lens 332 is downstream of the emitter 31 and upstream of the beam splitter 34. Along the transmission path of the echo light, the receiving lens 333 is downstream of the beam splitter 34 and upstream of the receiver 32. The emitting lens 332 includes at least one emitting lens. The receiving lens 333 includes at least one receiving lens. The transceiver lens 331 includes at least one transceiver lens.

Referring to FIG. 3, the extinction module includes a first extinctor 36, a second extinctor 37, and a third extinctor 38.

The first extinctor 36 is disposed at the outgoing end of the emitter 31, to eliminate stray light near the outgoing end of the emitter 31. Further, the first extinctor 36 may be disposed between the emitter 31 and the emitting lens 332.

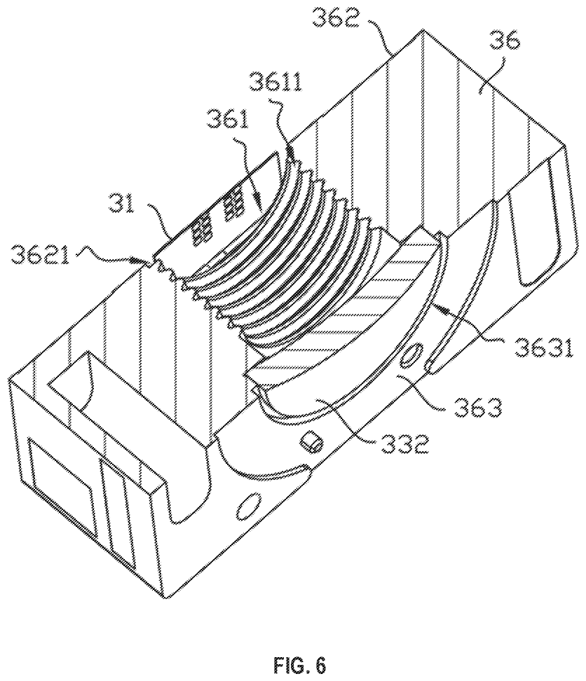

Referring to FIG. 6, the first extinctor 36 may be provided with a second light-transmitting hole 361 through which the detection light passes, and the inner wall surface of the second light-transmitting hole 361 is provided with at least one extinction groove 3611. When a plurality of extinction grooves 3611 are provided on the inner wall surface of the second light-transmitting hole 361, the plurality of extinction grooves 3611 may be sequentially arranged along the extending direction of the second light-transmitting hole 361. The extinction groove 3611 may be an annular groove. The cross section of the extinction groove 3611 may be an arc shape, a polygon, and the like, and the polygon may be a rectangle, a triangle, and the like.

The first extinctor 36 may include a first end face 362 and a second end face 363 that are arranged to face away from each other along the transmission path of the detection light. The first end face 362 may be provided with a first mounting groove 3621 communicated with the second light-transmitting hole 361, and at least a part of the emitter 31 may be located in the first mounting groove 3621. The second end face 363 may be provided with a second mounting groove 3631 communicated with the second light-transmitting hole 361, and at least a part of the emitting lens 332 may be located in the second mounting groove 3631. The first mounting groove 3621 may be capable of positioning the mounting position of the emitter 31, to improve assembly accuracy, assembly efficiency, and assembly stability of the emitter 31 and the first extinctor 36. The second mounting groove 3631 may be capable of positioning the mounting position of the emitting lens 332, to improve assembly efficiency, assembly efficiency, and assembly stability of the emitting lens 332 and the first extinctor 36.

The first extinctor 36 may further be provided with a weight reduction hole or the like to reduce the weight of the first extinctor 36.

Referring to FIG. 3, the second extinctor 37 is disposed at the receiving end of the receiver 32, to eliminate stray light near the receiving end of the receiver 32. Because there is reflection on the surface of the receiver 32, when the echo light is detected by the receiver 32, part of the echo light is reflected to form the stray light, and the stray light may interfere with other receivers 32, especially when a target object is a highly reflective target or a target object is close to the LiDAR 3, the stray light near the receiver 32 is more severe. The second extinctor 37 is disposed to eliminate the stray light near the receiver 32, thereby reducing interference of the stray light.

In an embodiment, the second extinctor 37 may include a first sub-extinctor 371 and a second sub-extinctor 372. The first sub-extinctor 371 may be located between the receiving lens 333 and the receiver 32, and the second sub-extinctor 372 may be located between the beam splitter 34 and the receiving lens 333.

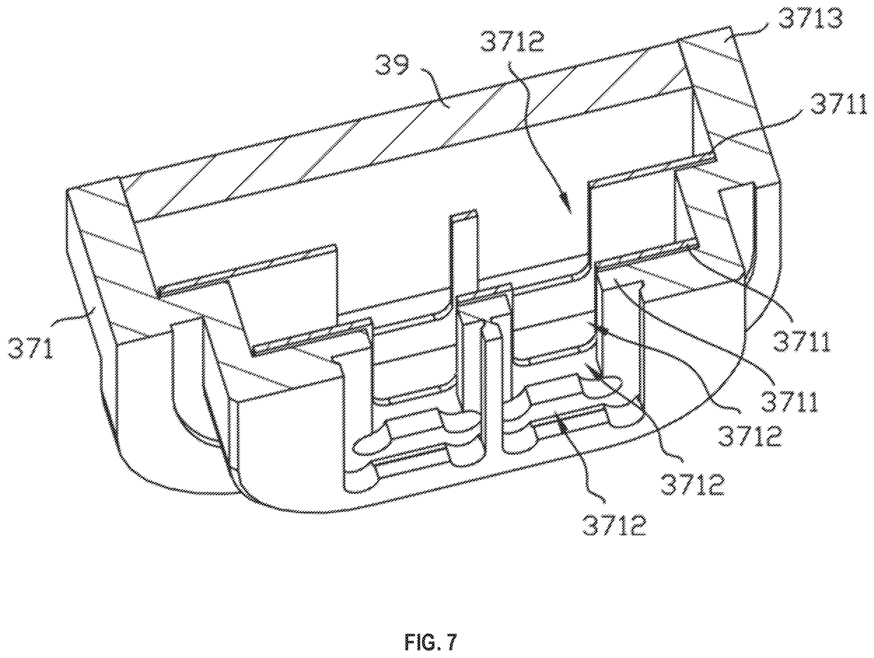

Referring to FIG. 7, the first sub-extinctor 371 includes a plurality of extinction diaphragms 3711 provided along the transmission path of the echo light, and at least one third light-transmitting hole 3712 is provided on the extinction diaphragm 3711. The echo light can pass through the third light-transmitting hole 3712 of the extinction diaphragm 3711 to reach the receiver 32, while the stray light is blocked by the extinction diaphragm 3711 and cannot pass through the third light-transmitting hole 3712, so that the stray light cannot reach the receiver 32, thereby improving the detection accuracy of the LiDAR 3.

Along the transmission path of the echo light, the adjacent extinction diaphragms 3711 can be arranged at intervals, or can be arranged in a stacked manner, or some of the extinction diaphragms 3711 can be arranged at intervals and the others can be arranged in a stacked manner, which is not limited.

When the two adjacent extinction diaphragms 3711 are arranged at intervals, surfaces opposite to each other between the two adjacent extinction diaphragms 3711 can also reflect at least some of the stray light at least once, to further reduce intensity of the stray light and reduce the impact of the stray light on the echo light. When the two adjacent extinction diaphragms 3711 are stacked, if a third through hole 3712 on the one extinction diaphragm 3711 is projected onto the first plane, and the projection is a first projection, and a projection of a third through hole 3712 on another adjacent extinction diaphragm 3711 is a second projection, the first projection may overlap with the second projection, and the remaining part of the first projection may be outside the second projection. The part of the first projection that overlaps with the second projection facilitates the echo light to pass through to reach the receiver 32, and the part of the first projection that is outside the second projection may cause the two adjacent extinction diaphragms 3711 to form a step surface at the third through hole 3712, so that the step surface can reflect at least some of the stray light at least once, to further reduce intensity of the stray light and improve detection accuracy of the LiDAR 3.

When the two adjacent extinction diaphragms 3711 are stacked, the two stacked adjacent extinction diaphragms 3711 can have an integral structure.

A third light passage 3712 may be provided on each extinction diaphragm 3711, or a plurality of third light passages 3712 may be provided on each extinction diaphragm 3711. The number of third light passages 3712 provided on each extinction diaphragm 3711 may be equal and approximately correspondingly arranged.

Referring to FIG. 7, the first sub-extinctor 371 may further include a mounting cylinder 3713, and a plurality of extinction diaphragms 3711 may be mounted in the mounting cylinder 3713. Further, the mounting cylinder 3713 may be provided with a step, and the extinction diaphragm 3711 may be disposed on a corresponding step, so that the extinction diaphragm 3711 is mounted and positioned in the mounting cylinder 3713. In some embodiments, at least a part of the extinction diaphragm 3711 may have an integral structure with the mounting cylinder 3713.

Further, the LiDAR 3 further includes an optical filter 39, and along the transmission path of the echo light, the optical filter 39 is located between the receiving lens 333 and the first sub-extinctor 371. The first sub-extinctor 371 is arranged between the optical filter 39 and the receiver 32. In this way, when the partial echo light is reflected by the receiver 32 to form the stray light, the stray light is transmitted towards the direction close to the receiver 32 again under the reflection of the optical filter 39, and the stray light is blocked by the extinction diaphragms 3711 during the transmission, thereby reducing interference with another receiver 32 and reducing the risk of the stray light. The optical filter 39 may be located in the mounting cylinder 3713.

Referring to FIG. 3, the second sub-extinctor 372 may include at least one extinction unit 3721, and the extinction unit 3721 may include a plurality of extinction teeth 3722 that are arranged at intervals along the transmission path of the echo light. The extinction tooth 3722 may reflect the at least part of the stray light at least once, so that the stray light is transmitted in a direction away from the receiver 32 or the intensity of the stray light is reduced, thereby reducing interference of the stray light to the echo light and improving the detection accuracy of the LiDAR.

Parameters such as density and depth of the extinction teeth 3722 can be adjusted flexibly based on an actual requirement. For example, the parameters such as density and depth of the extinction teeth 3722 can be adjusted based on a divergence angle and energy of a laser beam. Specifically, the density of the extinction teeth 3722 is related to the divergence angle of the laser beam; and the depth of the extinction teeth 3722 is related to the energy of the laser beam. In this embodiment, the density of the extinction teeth 3722 can be represented by a number of the extinction teeth 3722 in a unit area. The greater the density of the extinction teeth 3722, the smaller the distance between two adjacent extinction teeth 3722 can be. The smaller the density of the extinction teeth 3722, the greater the distance between two adjacent extinction teeth 3722 can be. The depth of the extinction teeth 3722 can be a size of the extinction teeth 3722 along a thickness direction of the LiDAR 3. The extinction teeth 3722 can be continuously provided along the thickness direction of the LiDAR 3, or can include a plurality of segments provided at intervals along the thickness direction of the LiDAR 3. The thickness direction of the LiDAR 3 is described in detail below.

In some embodiments, the second sub-extinctor 372 may include two extinction units 3721, and the two extinction units 3721 may be disposed on two opposite sides of the transmission path of the echo light. The density of the extinction teeth 3722 in the two extinction units 3721 may be the same or different.

Referring to FIG. 3, the third extinctor 38 is disposed between the transceiver lens 331 and the scanner 35 to eliminate stray light between the transceiver lens 331 and the scanner 35.

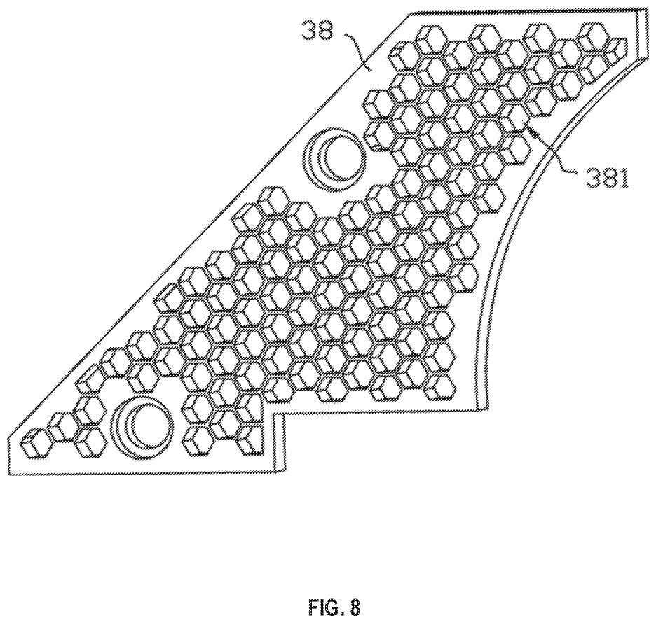

Referring to FIG. 8, in some embodiments, the third extinctor 38 is provided with a plurality of extinction holes 381, so that the stray light can be reflected multiple times in the extinction holes 381. The plurality of extinction holes 381 may be distributed in a hexagonal shape.

In an embodiment, the third extinctor 38 satisfy the following formula: Rₜₒₜₐₗ=n*R+(1−n)*R^{m}, where Rₜₒₜₐₗ is the overall reflectance of the third extinctor 38; R is the surface reflectance of the third extinctor 38; n is a filling ratio of a feature dimension of the third extinctor 38; and m is the number of reflections formed by the third extinctor 38. Because the more reflections of the stray light by the third extinctor 38, the greater the extinguishing capability, to achieve the best extinction effect, a greater value of Rtotal can be set. A greater value of n can be set to increase a value of Rtotal. In some embodiments, a cross section of the extinction hole 381 can have a substantially hexagonal structure, so that n is approximately set to the optimal value, to ensure that the stray light generated from each direction can be effectively suppressed and eliminated by the extinction hole 381.

Shapes and dimensions of the first extinctor 36, the second extinctor 37, and the third extinctor 38 can be flexibly adjusted in combination with a remaining space in the LiDAR 3.

The scanner 35 may include any device capable of changing a light transmission path, such as a galvanometer 351, a polygon mirror 352, a prism, or the like. In some embodiments, referring to FIG. 3, the scanner 35 includes the galvanometer 351 and the polygon mirror 352. Along the transmission path of the detection light, the galvanometer 351 is downstream of the transceiver lens 331, and the polygon mirror 352 is downstream of the galvanometer 351. Along the transmission path of the echo light, the polygon mirror 352 is upstream of the galvanometer 351, and the galvanometer 351 is upstream of the transceiver lens 331. The galvanometer 351 may have a first reflection surface 3511. The galvanometer 351 may rotate about a first axis X. The polygon mirror 352 may have a plurality of second reflection surfaces 3521 disposed around a second axis Y. The polygon mirror 352 may rotate about the second axis Y. The first axis X intersects the second axis Y. Further, the first axis X may be perpendicular to the second axis Y.

Further, the third extinctor 38 may be arranged in the region defined by the galvanometer 351, the polygon mirror 352, the transceiver lens 331, and the light transmission plate 41. Therefore, when the detection light is transmitted to the light transmission plate 41, if some of the detection light is reflected and scattered by the light transmission plate 41, and the reflected detection light forms the stray light, the third extinctor 38 may eliminate the stray light, thereby reducing the risk of the stray light. Similarly, if the detection light is transmitted to the galvanometer 351 and the polygon mirror 352, and the stray light is generated due to the reflection of some of the detection light, the stray light may also be eliminated by the third extinctor 38.

In some embodiments, the transition surface 3522 is provided between two adjacent second reflection surfaces 3521 of the polygon mirror 352. Compared with a direct connection between the two adjacent second reflection surfaces 3521 to form a sharp angle and an easily formed diffuse reflection at a corner, the transition surface 3522 is beneficial for controlling the reflection of the laser beam. The second reflection surface 3521 is configured to reflect the detection light and the echo light, and the transition surface 3522 can be used to balance the volume of the LiDAR, reduce the load capacity of the motor of the polygon mirror 352, reduce the risk of the stray light, and the like.

Here, the transition surface 3522 can be a plane, a curved surface, a combination of a plane, and a curved surface, or the like. The size of the transition surface 3522 can be related to a beam spot size of the detection light.

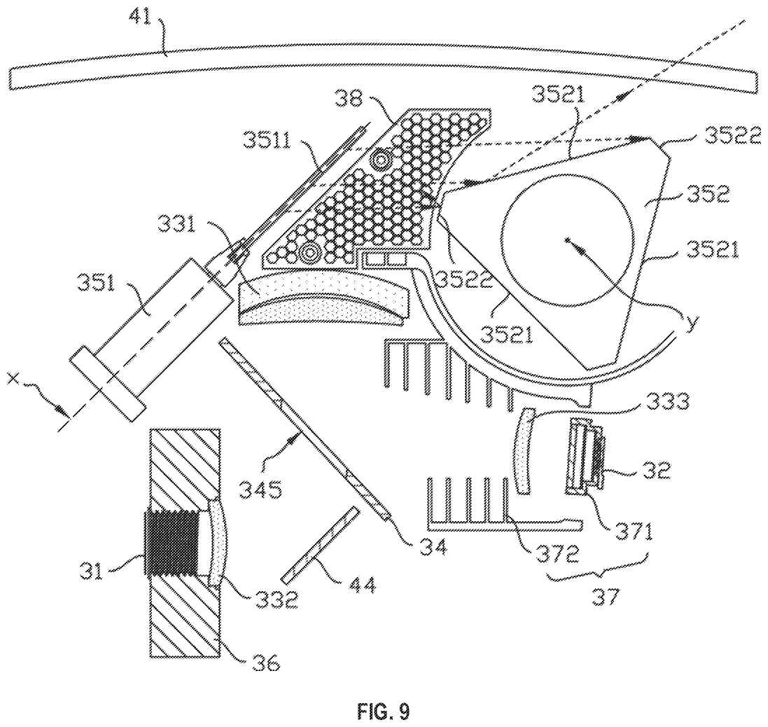

During rotation of the polygon mirror 352 along the second axis Y, the polygon mirror 352 can have a first position and a second position. Referring to FIG. 3, in the first position, the second reflection surface 3521 is opposite to the first reflection surface 3511, so that the detection light can be entirely transmitted to the second reflection surface 3521. In an embodiment, the polygon mirror 352 does not form the stray light. Referring to FIG. 9, in the second position, a part of the second reflection surface 3521 and at least a part of the transition surface 3522 can be opposite to the first reflection surface 3511. At this time, in the detection light reaching the polygon mirror 352, a part of the light may be transmitted to the second reflection surface 3521, a part of the light may be transmitted to the transition surface 3522 on the side of the second reflection surface 3521. A part of the light may be transmitted to the boundary line on the other side of the second reflection surface 3521 and pass through the boundary line, and the light may be irradiated to another structural member. When a part of the light is irradiated to the transition surface 3522 or another structural member, the stray light can be generated due to the diffuse reflection of the transition surface 3522 and another structural member, causing the light to return without detecting the target object outside the LiDAR 3, leading to a risk of stray light. Based on this, the transition surface 3522 can be provided with a reflection coating, so that the part of the light transmitted to the transition surface 3522 can reach the third extinctor 38 or the galvanometer 351 and be reflected to the third extinctor 38 by the galvanometer 351, to eliminate the stray light.

The third extinctor 38 may be provided on one side of the polygon mirror 352 along the second axis Y, and the transition surface 3522 is inclined relative to the second axis Y. In some embodiments, a distance between the transition surface 3522 and the second axis Y may gradually increase along a direction from the third extinctor 38 to the polygon mirror 352, to ensure that the transition surface 3522 can transmit the reflected light to the third extinctor 38 and the reflected light is extinguished by the third extinctor 38.

The LiDAR 3 further includes a housing 42. The housing 42 is formed with a mounting cavity 421. The emitter 31, the receiver 32, the transceiver lens 331, the emitting lens 332, the receiving lens 333, the beam splitter 34, the scanner 35, the first extinctor 36, the second extinctor 37, and the third extinctor 38 may all be disposed in the mounting cavity 421.

The housing 42 can include a side plate 422 and two end plates 423. The two end plates 423 can be disposed on two opposite sides of the side plate 422 and can be connected to the side plate 422. The mounting cavity 421 can be defined between the two end plates 423 and the side plate 422. A window (not shown in the figure) can be disposed on one side of the side plate 422, and the transmissive plate 41 can be mounted on the window. A thickness direction of the LIDAR 3 can be roughly from one end plate 423 to the other end plate 423.

An isolation member 43 may be disposed between two adjacent components along the transmission path of the detection light and/or the transmission path of the echo light. The isolation member 43 may be provided with an optical path channel (not shown in the figure), so that the optical path between two adjacent components can be transmitted in the optical path channel of the isolation member 43. For example, along the transmission path of the detection light, the isolation member 43 or the like may be disposed between the emitting lens 332 and the beam splitter 34, or between the beam splitter 34 and the transceiver lens 331; along the transmission path of the echo light the isolation member 43 or the like may be disposed between the transceiver lens 331 and the beam splitter 34, or between the beam splitter 34 and the receiver 32.

In some embodiments, the LiDAR 3 further includes an optical path switching element 44, and along the transmission path of the detection light, the optical path switching element 44 is disposed between the emitting lens 332 and the beam splitter 34. The optical path switching element 44 is disposed to adjust the transmission path of the detection light, which is beneficial for flexible arrangement of various components and realization of a miniaturized design of the LiDAR 3. The optical path switching element 44 may be a reflection mirror, a prism, and the like, which is not limited thereto.

The terms such as “first” and “second” are merely intended for a purpose of description, and should not be understood as an indication or implication of relative importance. Unless otherwise stated, “a plurality of” means at least two, for example, two, three, four, and the like. “And/or” describes an association relationship of associated objects, and indicates that there can be three relationships. For example, A and/or B can indicate that there are three cases: only A exists, both A and B exist, and only B exists. A character “/” generally indicates an “or” relationship between the associated objects.

What is claimed is:

1. A LIDAR, comprising:
an emitter, wherein the emitter is configured to emit detection light to a target object in a target region;
a receiver, wherein the receiver is configured to receive echo light reflected by the target object;
a beam splitter, wherein the beam splitter is downstream of the emitter along a transmission path of the detection light, and the beam splitter is upstream of the receiver along a transmission path of the echo light;
a transceiver lens, wherein the transceiver lens is downstream of the beam splitter along the transmission path of the detection light, and the transceiver lens is upstream of the beam splitter along the transmission path of the echo light;
a scanner, wherein the scanner is downstream of the transceiver lens along the transmission path of the detection light, and the scanner is upstream of the transceiver lens along the transmission path of the echo light; and
an extinction module, wherein the extinction module includes a first extinctor, a second extinctor, and a third extinctor, the first extinctor is positioned at an outgoing end of the emitter, the second extinctor is positioned at a receiving end of the receiver, and the third extinctor is positioned between the transceiver lens and the scanner.

2. The LiDAR according to claim 1, wherein the beam splitter includes a reflection part and a transmission part connected to the reflection part, the reflection part is configured to reflect one of the detection light and the echo light, the transmission part is configured to transmit the other one of the detection light and the echo light, and the transmission part is recessed relative to the reflection part; or
wherein the beam splitter is provided with a first light-transmitting hole, the beam splitter is configured to reflect one of the detection light and the echo light, and the first light-transmitting hole is configured to transmit the other one of the detection light and the echo light.

3. The LiDAR according to claim 1, wherein the first extinctor is provided with a second light-transmitting hole through which the detection light passes, and an inner wall surface of the second light-transmitting hole is provided with at least one extinction groove, and the extinction groove is an annular groove.

4. The LiDAR according to claim 3, wherein the first extinctor is provided with a first end face and a second end face that are arranged to face away from each other along the transmission path of the detection light;
wherein the first end face is provided with a first mounting groove communicated with the second light-transmitting hole, and at least a part of the emitter is positioned in the first mounting groove; and/or
wherein the LiDAR further includes an emitting lens, the emitting lens is downstream of the emitter along the transmission path of the detection light, and the emitting lens is upstream of the beam splitter along the transmission path of the detection light, the second end face is provided with a second mounting groove communicated with the second light-transmitting hole, and at least a part of the emitting lens is positioned in the second mounting groove.

5. The LiDAR according to claim 1, further including a receiving lens, wherein the receiving lens is downstream of the beam splitter along the transmission path of the echo light, and the receiving lens is upstream of the receiver along the transmission path of the echo light, and the second extinctor includes:
a first sub-extinctor, wherein the first sub-extinctor is positioned between the receiver and the receiving lens; and
a second sub-extinctor, wherein the second sub-extinctor is positioned between the beam splitter and the receiving lens.

6. The LiDAR according to claim 5, wherein the first sub-extinctor includes:
a plurality of extinction diaphragms, wherein the plurality of extinction diaphragms are sequentially arranged along the transmission path of the echo light, and each extinction diaphragm is provided with at least one third light-transmitting hole; and a gap is provided between two adjacent extinction diaphragms, and/or the two adjacent extinction diaphragms are disposed in a stacked manner.

7. The LiDAR according to claim 6, further including an optical filter, wherein the optical filter is downstream of the receiving lens along the transmission path of the echo light, and the optical filter is upstream of the receiver along the transmission path of the echo light, and the first sub-extinctor further includes:
a mounting cylinder, wherein the plurality of extinction diaphragms and the optical filter are all positioned in the mounting cylinder, and the receiver is connected to the mounting cylinder.

8. The LiDAR according to claim 5, wherein the second sub-extinctor includes:
two extinction units, wherein the two extinction units are on two opposite sides of the transmission path of the echo light, and each extinction unit includes a plurality of extinction teeth that are arranged at intervals along the transmission path of the echo light.

9. The LiDAR according to claim 1, wherein the scanner includes:
a galvanometer, wherein the galvanometer is provided with a first reflection surface, and the galvanometer is configured to rotate around a first axis;
a polygon mirror, wherein the polygon mirror is provided with a plurality of second reflection surfaces that are arranged around a second axis, and the polygon mirror is configured to rotate around the second axis, and the second axis intersects the first axis; and
two adjacent second reflection surfaces of the polygon mirror are connected through a transition surface, and the transition surface is provided with a reflection coating.

10. The LiDAR according to claim 9, wherein the third extinctor is on one side of the polygon mirror along the second axis, and the transition surface is inclined relative to the second axis; and
wherein the third extinctor includes a plurality of extinction holes, and a cross section of the extinction hole is a hexagon.
